(19) United States
(12) Patent Application Publication
(10) Pub. No.: US 2013/0241535 A1
(43) Pub. Date: Sep. 19, 2013

(54) Method for Verifying an Electrical Connection Between a Generator and an Inverter

(71) Applicant: SMA SOLAR TECHNOLOGY AG, Niestetal (DE)

(72) Inventors: Bjoern Magnussen, Kassel (DE); Heiko Pruessing, Neuental (DE)

(73) Assignee: SMA Solar Technology AG, Niestetal (DE)

(21) Appl. No.: 13/869,172

(22) Filed: Apr. 24, 2013

Related U.S. Application Data
(63) Continuation of application No. PCT/EP2011/069765, filed on Nov. 9, 2011.

(30) Foreign Application Priority Data
Nov. 10, 2010 (DE) 102010050785.7

(51) Int. Cl. G01R 31/04

(52) U.S. Cl. CPC G01R 31/04
USPC 324/126

(57) ABSTRACT

A method of verification of an electrical connection between a generator and an inverter by a cable is disclosed. The method includes placing a handheld device with a current detection sensor in vicinity of a cable. A command to change a current is transmitted from the handheld device to the inverter to generate a current signature within an inverter-generator connection cable. A sensor signature is detected by the current detection sensor and compared to the current signature caused by the command to change a current. A verification signal based on the comparison is generated. The method may be used to compile a wiring plan between a plurality of generators and a plurality of inverters.

### REFERENCE TO RELATED APPLICATIONS

This application is a continuation application of International Application No. PCT/2011/069765, filed on Nov. 9, 2011, which claims priority to German Patent Application No. 10 2010 050 785.7, filed on Nov. 10, 2010, the contents both of which are hereby incorporated by reference in their entirety.

### FIELD

The disclosure relates to a method for verifying an electrical connection between a generator and an inverter. The disclosure further relates to a method for creating a plan of a wiring for connecting a plurality of generators with a plurality of inverters. The disclosure further relates to an according program application.

### BACKGROUND

In times of increasing scarcity and increasing pricing of fossile energy sources, the significance of producing energy from regenerative energy sources is increasing. Accordingly, a portion of electrical energy produced by photovoltaics is increasing. In this context, a photovoltaic (PV-) system typically comprises the PV-generator for converting the sunlight into DC current and an inverter to convert the generated DC current into an AC current conformal for feed into a grid. To achieve a high feed in power, a plurality of PV-generators is either connected with a single or a few centralized inverters, or with a plurality of smaller, decentralized inverters. In the latter case, the average length of the wiring between the generator and the associated inverter is reduced. On the other hand, problems frequently arise for the installation or maintenance personnel to determine the connection of a PV-generator or wiring under test with an associated inverter. While constructing the PV-system, the effort of creating a system wiring plan is often avoided and a unique labeling of the wiring or the generators is omitted.

### SUMMARY

The disclosure provides a method for the installation or service staff to verify the electrical connection between a generator and an associated inverter in a simple and reliable manner. This is realized through a method. By practicing the method according to the disclosure it is further possible to create a wiring plan of a power generation system with a plurality of generators and a plurality of inverters after construction of the system with a comparably low effort.

A technician places a handheld device into the vicinity of one of the cables with which the electrical connection between a generator and an inverter is carried out.

Subsequently, a command to produce a current signature of the generator current (i.e. the current through the connection wire between the generator and the inverter) is created by a software application installed on the handheld device and sent to an inverter in order to execute the command. In parallel with the generation of the current signature, a sensor signature is recorded by means of a current sensor, for example a magnetic field sensor such as a Hall effect sensor. The current sensor is comprised in the handheld device or connected to the device by a cable (e.g. via the earphone/microphone plug) or by radio transmission such as Bluetooth. If the cable positioned in the vicinity of the current sensor is part of the electrical connection between the generator and the inverter, so that the current in the cable varies according to the current signature, this variation is detected by a comparison between the current signature and the sensor signature. In this way, it is possible to verify by a comparison of both signatures, whether an electrical connection between the generator and the respective inverter exists via the cable.

Since various mobile phones available today comprise magnetic field sensors suitable as current sensors, for example as part of an electronic compass, and these mobile phones further comprise components required for data and communication purposes, no specific hardware may be required to perform the method. It is sufficient to program a software application to execute the method and to install this application on the mobile phone. Such mobile phones often further comprise an integrated GPS receiver, thereby allowing to determine the location coordinates of the handheld device while executing the method described.

The current signature may comprise a command to switch off and switch on the generator current, or it may comprise one or more commands suitable to change the actual generator current from a first value to a second value, so that for example a predetermined sequence of changes between different values of the generator current is generated. In one embodiment, the command to generate the current signature comprises a command to execute a search for a global maximum power point of the generator. Within such a search a voltage range of the generator is scanned, wherein the generator current is varied according to the generator characteristics leading to the generation of the current signature suitable to be analyzed by the method according to the disclosure. In this way, the temporary loss of generator power caused by the generation of the current signature may be partly or fully compensated.

In order to check a group of inverters with regard to the electrical connection of the generator under test, the method can be executed either with a single inverter or with a subgroup of the group of inverters. The separation of the group into subgroups is continued until the method results in a successful verification signal identifying a single inverter. This way, a few attempts are sufficient to determine, which inverter of a possibly large group of inverters is electrically connected to the generator under test. Thus, a determination is possible in a fast way and with a low consumption of power.

After successful verification of the electrical connection, the respectively identified inverter may transmit to the handheld device data specific to the connection, such as the actual generator current, the generator voltage, or a unique inverter identification. The handheld device may show this data on its display. This way, the technician may obtain fast and precise information of the system without the need for performing complex measurements. The maintenance of the power generation system is thereby significantly simplified.

The transmission of the command to generate the current signature may be performed by any known data transmission method, such as by cable communication or by wireless communication such as a radio connection. The transmission path may be a direct path from the handheld device to the respective inverter, but may as well extend from the handheld device to a first inverter forming a network for data exchange with a group of further inverters. In this case, the command is transmitted to the inverter under test using the network. It is also possible to establish a data connection between the handheld device and the Internet, thereby transmitting the command further from the Internet to the inverter under test.

If the handheld device is further capable to detect its location, for example by a GPS receiver, the coordinates of the location of the handheld device while generating the current signature may be determined and stored. This way it is possible to combine the information about the position of the handheld device as information representing the approximate location of the generator with the information of the identity of the respective inverter and to store this combined information into a database. When performing this method iteratively with a plurality of generators, a wiring plan of the power generation system may be generated or verified in a simple and reliable manner.

In order to increase the reliability of the method, it may be contemplated to repeat the method using the same inverter under test and to modify the position and/or the orientation of the handheld device between the repetitions. Details about how to modify the location and or orientation may be given to the technician by the application installed on the handheld device, for example by graphical symbols. To improve the precision of the different locations and/or orientations, the handheld device may comprise a clamping device such as a clip with a rotatable fixture. The clamping device is used to define the location and/or orientation of the handheld device relative to the cable under test while performing the method for verification of the electrical connection. The application may average between the results of the repetitions or may select the best adjustments to perform the comparison between the current signature and the sensor signature. It may as well be contemplated to select a current signature from a set of different predetermined signatures in response to a signal level of the sensor signature in order to increase the reliability of the verification. Optionally, the various orientations and/or locations of the handheld device may be determined by inertia sensors, acceleration sensors, or location sensors in order to take into account and/or compensate for the changes of orientation.

### BRIEF DESCRIPTION OF THE DRAWINGS

In the following the disclosure is described by means of figures. The figures are only used to illustrate details, and are not intended to limit the claimed invention. The figures show:

FIG. 1 is a schematic drawing of a power generation system with components required to perform the inventive method according to one embodiment,

FIG. 2 illustrates example generator characteristics,

FIG. 3 is an example current signature, and

FIG. 4 is a flow diagram showing a process flow according to one embodiment.

### DETAILED DESCRIPTION

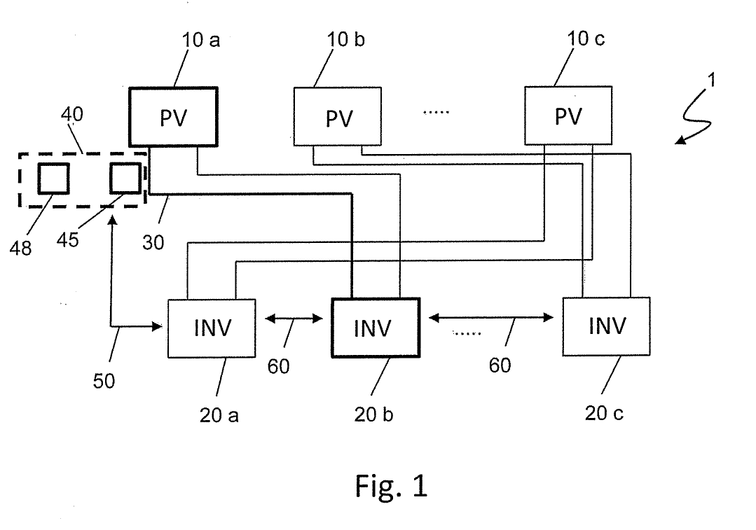

FIG. 1 shows a power generation system 1 comprising a plurality of generators 10a, 10b, 10c each connected to one inverter of a plurality of inverters 20a, 20b, 20c by a respective cable. The cables are used to transfer the electrical power generated as DC current by the generators 10a, 10b, 10c to the associated inverter. A handheld device 40 comprises a current sensor 45 as well as a GPS receiver 48. The handheld device 40 may for example be a so-called Smartphone comprising an integrated GPS receiver as well as a magnetic field sensor, e.g. as a component of an electronic compass. With such a magnetic field sensor the strength and the direction of a magnetic field can be measured, thereby allowing one to determine a DC current flowing through a cable 30 placed in the vicinity of the magnetic field sensor. Vicinity in this context refers to a distance range between the magnetic field sensor 45 and the cable 30 under test, in which the magnetic field caused by the DC current can be clearly distinguished from the magnetic field existing at the location of the cable 30 for any other reason (such as the Earth's magnetic field, magnetic fields by permanent magnets or magnetic fields caused by other currents). In one embodiment, the magnetic field caused by the cable's DC current exceeds the Earth's magnetic field at the location of the cable 30. From this consideration, a range of distances between 1 mm and approximately 3 cm between the magnetic field sensor 45 and the cable 30 under test can be derived in practical applications. By wrapping the cable 30 under test around the magnetic field sensor 45 once or multiple times, the magnetic field caused by the DC current and hence the sensitivity of the measurement can be further enhanced.

In order to perform the method, the handheld device 40 with its magnetic field sensor 45 is placed in the vicinity of the cable 30 which is assumed to provide an electrical connection to be verified between the generator 10a and the inverter 20b. Subsequently, the handheld device 40 transmits a command to change a current using the transmission path 50. The command to change a current comprises a unique identification of the inverter executing the command. Optionally, the command to change a current further comprises coordinates generated by the GPS receiver 48 of the handheld device 43 representing the actual location of the handheld device 40 and accordingly the location of the cable 30 providing electrical connection to be verified.

The transmission path 50 may comprise a cable connection or a radio connection such as Bluetooth, wireless LAN, UMTS or other wireless communication protocols. The transmission path 50 may be a direct data connection between the handheld device 40 and the inverter executing the command to change a current, or the transmission path 50 makes use of a network 60 formed between the plurality of inverters 20a, 20b, 20c. This way it is possible to address inverters located outside the range for a direct data connection to the handheld device 40.

The command to change a current may comprise a command that causes the inverter under test to modify the current flowing from a generator connected to the inverter. The variation of the current will be labeled in the following as a current signature. For example, the inverter may reduce the current temporarily or permanently to zero or to any other predetermined current value while executing the command to modify the current. This control can be established by a current set point or by other means such as setting a value for the generator voltage.

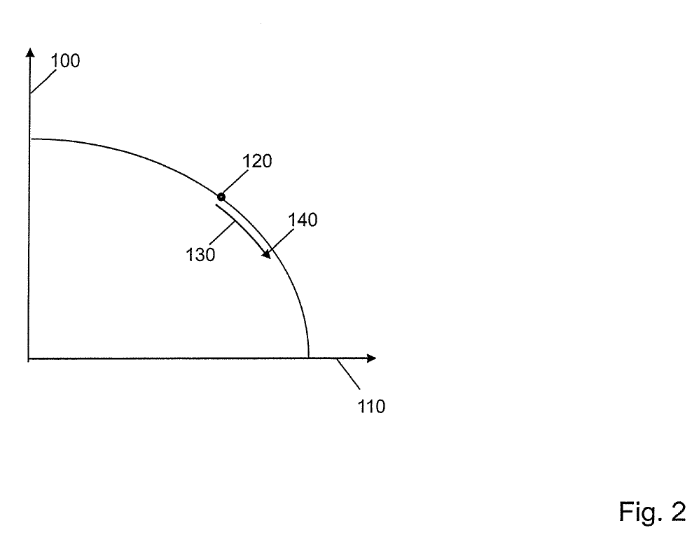

FIG. 2 shows the generator characteristics 140 indicating a generator current 100 as a function of a generator voltage 110. The actual mode of operation of the generator is defined by the working point 120. Any change of the mode of operation causes a variation 130 of the working point along the generator characteristics 140 with an associated change of the generator current 100.

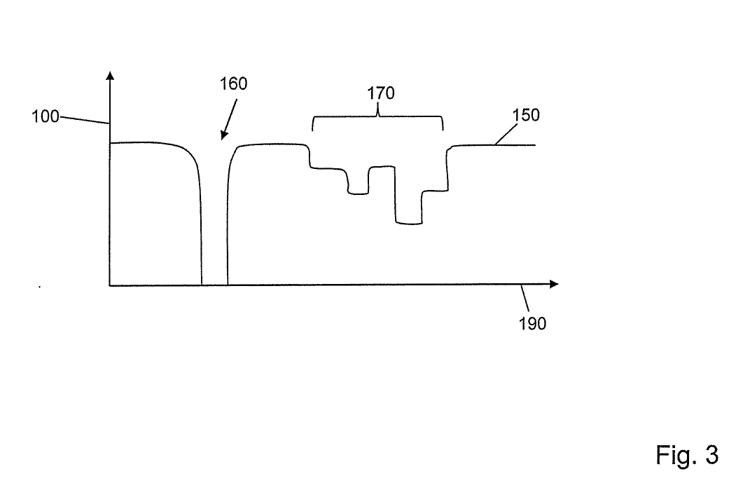

As a consequence, the command to change a current leads to a change of the working point 120 according to the generator characteristics 140 resulting in a generated current signature 150, i.e. a change of the generator current 100 along the time axis 190, as shown in FIG. 3. This way, a command to change a current, which effects a temporary switching off and subsequent switching on of the generator current 100 while executing the command, results in a switching signature 160. A different form of a current signature 150 is generated, if the command to change a current leads to a setting of a sequence of predetermined current values by the inverter during execution of the command. In this case, the signature may result in a current sequence signature 170 as shown. It is as well contemplated to increase the generator current 100 temporarily or permanently during execution of the command to change a current.

In a further embodiment, the command to change a current may comprise a command to execute a search algorithm to identify a maximum power point of the generator. Within such a search, a range of the generator voltage 110 is scanned to identify a working point 120 with a maximum power output of the generator. Such a search algorithm therefore also causes a temporary change of the generator current and hence a current signature.

If a varying current flow caused by the command to change a current is effected in the cable 30, in the vicinity of which the current sensor 45 of the handheld device 40 is placed, the current signature may be measured as a respective sensor signature. By comparison of the current signature and the sensor signature it is possible to verify whether the cable 30 is part of the electrical connection between the generator and the inverter 20b addressed by the command to change a current. In case the comparison provides a sufficient degree of identity between the current signature and the sensor signature, the handheld device 40 generates a verification signal indicating successful identification, otherwise a verification signal indicating failed identification or no verification signal is generated. The verification signal generated can be used to show a corresponding success indicator on the display of the handheld device, or can be transmitted along the transmission path 50 to a data processing system connected and/or to the inverter 20b addressed.

As far as multiple inverters are potentially connected to the cable 30 under test, the verification may be performed in sequential process parts, wherein in each process part a single inverter or a subset of inverters is used, until the inverter 20b connected to the cable 30 under test is unambiguously identified.

It may alternatively be considered to generate an individual current signature using multiple or even all potential inverters at the same time or within a given joint time period, thereby detecting based on the sensor signature which of the inverters is connected to the cable under test. This way, the process of identification may be significantly simplified and accelerated.

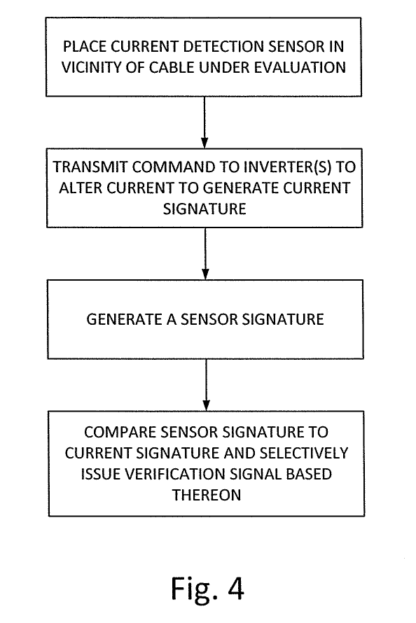

A flow diagram of a process according to an aspect of the disclosure is shown in FIG. 4. At 200, the handheld device 40 is placed with its current detection sensor 45 in the vicinity of the cable 30 under test. In one embodiment, the handheld device 40 may comprise a fixture to ensure that the handheld device 40 has the predefined distance as well as a predefined alignment to the cable 30. Optionally, the handheld device 40 may subsequently use a calibration measurement to ensure that the conditions to detect the current signature by means of the current detection sensor 45 are met, or whether the current detection sensor 45 generates a signal too large to provide a sufficient sensitivity to detect an additional signal component of the current signature. If required, the handheld device 40 generates instructions based on the result of the calibration measurement on how to modify a distance or alignment in order to achieve a sufficient or optimum sensitivity of the current detection sensor 45.

At 210, the handheld device 40 transmits a command to change a current to a single inverter or to a group of inverters. As described above, the communication functionality of the handheld device 40 is used. The command to change a current is configured to modify the generator current of the generator connected to the inverter upon execution of the command, thereby generating the current signature on the power carrying cables between the respective generator and inverter.

The current detection sensor 45 generates a sensor signature comprising a sequence of measured values of the current detection sensor at 220. During this time, distance and alignment of the handheld device 40 are kept constant in order to avoid influencing the detection of the sensor signature.

At 230, the sensor signature is compared to the current signature and a verification signal is generated based on the result of this comparison. Based on known algorithms, a degree of conformity between the signatures in shape and synchronicity is determined. If the degree of conformity determined exceeds a predetermined value, identity of both signatures is recognized and a verification signal indicating success is generated. This signal may comprise displaying the success in a graphical way on the display of the handheld device 40 or signaling the success acoustically. Alternatively or additionally, the result of the comparison may as well be transmitted to further devices connected to the handheld device 40 by its communication components (optionally together with the actual GPS coordinates of the handheld device 40), in particular to the inverter 20b that was addressed for generating the current signature.

For increasing the reliability of the verification, the handheld device may be configured to perform a repetitive transmission of the command to change a current and a repetitive detection of the sensor signature. Between the repetitions, the handheld device may request the user by means of an adequate display, to change the alignment and/or the distance of the handheld device 40. The comparison between the current signature and the sensor signature may in this case be performed as a combination of the repeated single comparisons, and subsequently the verification signal is generated.

In an embodiment, the inverter 20b involved may subsequently transmit data values to the handheld device 40, in particular data values concerning the electrical connection being verified, and the handheld device may show these data values on its display. Such data values may comprise actual current, voltage, or power values of the generator, logistical data such as an inverter identification, its position, error messages or performance figures determined and saved over a period of time, or other values. This way, service staff may draw conclusions on the status of the power generation system one in a simple, fast and reliable manner, and may decide on maintenance actions required. Beside the handheld device 40, which may be a conventional Smartphone, and a suitable program application, no further components to perform the method according to the disclosure and to perform a diagnosis of the power generation system 1 are required.

By means of the data determined about the verified electrical connection between a generator and an inverter, a wiring plan of the power generation system may be compiled, i.e. generated, extended, or corrected, by comparing or adding the results of the method according to the invention to the information from an existing wiring plan about the electrical connections between the generators and the inverters. In case that GPS coordinates have been determined during verification, this wiring plan may also comprise a plan of the spatial arrangement of the plurality of generators.

The person skilled in the art will recognize further combinations of the embodiments shown using the present description and will contemplate other variations and equivalents of the processes and methods described and the components used, which are considered to be included by the following claims. The scope of the invention shall therefore be considered to be limited solely by the wording of the following claims.

1. A method of verifying an electrical connection between a generator and an inverter by a cable, comprising:
placing a handheld device comprising a current detection sensor in a vicinity of a cable under evaluation,
transmitting a command to change a current from the handheld device to the inverter to generate a current signature within the cable connecting the inverter with the generator,
detecting a sensor signature associated with the cable under evaluation by the current detection sensor, and
generating a verification signal based on a result of a comparison of the sensor signature and the current signature, wherein the verification signal is indicative of whether the cable under evaluation is the cable connecting the inverter with the generator.

2. The method according to claim 1, wherein the current signature comprises a switching signature.

3. The method according to claim 1, wherein the current signature comprises a current sequence signature of the generator current.

4. The method according to claim 1, wherein the command to change a current comprises a command to execute a global search for a point of maximum generator power.

5. The method according to claim 1, further comprising determining GPS coordinates by the handheld device, wherein the GPS coordinates are saved in case of the verification signal indicating that the cable under evaluation is the cable connecting the inverter with the generator.

6. The method according to claim 6, wherein the command to change a current is transmitted repetitively, and the sensor signature is detected repetitively, wherein a position of the handheld device relative to the cable is varied between repetitions.

7. The method according to claim 1, wherein the current detection sensor comprises a hall effect sensor.

8. The method according to claim 1, wherein the command to change a current is transmitted by the handheld device via a radio transmission.

9. The method according to claim 1, wherein the command to change a current is transmitted by the handheld device using a network between a plurality of inverters.

10. The method according to claim 1, wherein the handheld device comprises a Smartphone comprising a magnetic field sensor.

11. The method according to claim 1, wherein the method is repeated addressing different inverters of a plurality of inverters until the verification signal indicates that the cable under evaluation is the cable connecting the inverter with the generator.

12. The method according to claim 1, wherein data specific to the verified connection is transmitted from the inverter to the handheld device, if the verification signal indicates that the cable under evaluation is the cable connecting the inverter with the generator.

13. The method according to claim 1, wherein the command to change a current is transmitted to a plurality of inverters, wherein each inverter of the plurality of inverters is generating a different current signal.

14. A method of compiling a wiring plan between a plurality of generators and a plurality of inverters, comprising:
placing a handheld device comprising a current detection sensor in a vicinity of a cable under evaluation,
transmitting a command to change a current from the handheld device to the inverter to generate a current signature within a cable connecting one of the inverters with one of the generators,
detecting a sensor signature associated with the cable under evaluation by the current detection sensor,
generating a verification signal based on a result of a comparison of the sensor signature and the current signature, wherein the verification signal is indicative of whether the cable under evaluation is the cable connecting the one of the inverters with the one of the generators,
noting the connection between the one of the inverters and the one of the generators if the verification signal is positive, and
repeating the acts above until a positive verification signal is obtained for each cable present between the plurality of generators and the plurality of inverters.

15. A program application comprising instructions stored on a non-transitory medium for use with a handheld device comprising a current detection sensor and being placed in a vicinity of a cable, wherein a method for verifying an electrical connection between a generator and an inverter by a cable is carried out when the program application is executed by a processor of the handheld device, comprising:
placing the handheld device comprising the current detection sensor in a vicinity of a cable under evaluation,
transmitting a command to change a current from the handheld device to the inverter to generate a current signature within the cable connecting the inverter with the generator,
detecting a sensor signature associated with the cable under evaluation by the current detection sensor, and
generating a verification signal based on a result of a comparison of the sensor signature and the current signature, wherein the verification signal is indicative of whether the cable under evaluation is the cable connecting the inverter with the generator.
